(19) United States
(12) Patent Application Publication
(10) Pub. No.: US 2026/0269841 A1
(43) Pub. Date: Sep. 10, 2026

(54) COMPRESSION DEVICE, MEMORY SYSTEM AND COMPRESSION METHOD

(71) Applicant: Kioxia Corporation, Tokyo (JP)

(72) Inventors: Masato SUMIYOSHI, Yokohama Kanagawa (JP); Keiri NAKANISHI, Kawasaki Kanagawa (JP)

(21) Appl. No.: 19/326,318

(22) Filed: Sep. 11, 2025

(30) Foreign Application Priority Data
Mar. 10, 2025 (JP) 2025-037377

(51) Int. Cl. H03M 7/30; G11C 16/08; G11C 16/26; H03M 7/40

(52) U.S. Cl. CPC H03M 7/3088; G11C 16/08; G11C 16/26; H03M 7/4093

(57) ABSTRACT

A compression device is configured to perform dictionary-based coding and entropy coding on first data that is continuously input. The compression device includes a first encoder configured to perform the dictionary-based coding with respect to the first data to generate a first symbol, a first converter configured to convert the first symbol into a plurality of second symbols and cyclically output one of the plurality of second symbols per cycle, a first buffer that stores each of the plurality of second symbols output from the first converter, a generator configured to generate an encoding table for the entropy coding, and a second encoder configured to cyclically read out one of the second symbols from the first buffer per cycle after the encoding table is generated, and perform the entropy coding with respect to a bit sequence comprising the plurality of second symbols with reference to the generated encoding table.

### CROSS-REFERENCE TO RELATED APPLICATIONS

This application is based upon and claims the benefit of priority from Japanese Patent Application No. 2025-037377, filed Mar. 10, 2025, the entire contents of which are incorporated herein by reference.

### FIELD

Embodiments described herein relate generally to a compression device, a memory system and a compression method.

### BACKGROUND

There is known a memory system equipped with a compression device that is configured to compress data in order to make effective use of a storage space. In such a memory system, when a write command is issued from a host connected to the memory system, it is possible to compress data specified in the write command and write the compressed data into a non-volatile memory. It is noted that compressing data means reducing the amount of data by converting the data into a code assigned to the data (i.e., encoding the data).

Here, as a compression method to compress data as described above, for example, a compression method in which dictionary-based coding and entropy coding are combined with each other is sometimes adopted, and there is a demand for miniaturizing a compression device that compresses data using this compression method.

### BRIEF DESCRIPTION OF THE DRAWINGS

FIG. 1 is a diagram schematically showing an example of the hardware configuration of a memory system according to a first embodiment.

FIG. 2 is a diagram for explaining an example of the configuration of a compression device according to a comparative example of the first embodiment.

FIG. 3 is a diagram for explaining the width of a delay buffer in the comparative example of the first embodiment.

FIG. 4 is a diagram for explaining the width of the delay buffer in the comparative example of the first embodiment.

FIG. 5 is a diagram showing an example of the configuration of the compression device according to the first embodiment.

FIG. 6 is a diagram for explaining an overview of the operation of a compression device according to the first embodiment.

FIG. 7 is a flowchart showing an example of the processing procedure of first conversion processing in the first embodiment.

FIG. 8 is a flowchart showing an example of the processing procedure of second conversion processing in the first embodiment.

FIG. 9 is a diagram for explaining another example of a sub-symbol in the first embodiment.

FIG. 10 is a diagram for explaining an example of a sub-symbol in a second embodiment.

FIG. 11 is a diagram showing an example of the configuration of a compression device according to the second embodiment.

FIG. 12 is a diagram for explaining the operation of a table generating unit in the second embodiment.

FIG. 13 is a diagram schematically showing an example of the configuration of a frequency table update circuit in the first embodiment.

FIG. 14 is a diagram schematically showing an example of the configuration of the frequency table update circuit in the second embodiment.

FIG. 15 is a flowchart showing an example of the processing procedure of first conversion processing in the second embodiment.

FIG. 16 is a flowchart showing an example of the processing procedure of second conversion processing in the second embodiment.

FIG. 17 is a diagram showing an example of the configuration of a compression device according to a third embodiment.

FIG. 18 is a diagram schematically showing an example of the configuration of an entropy encoding circuit in the second embodiment.

FIG. 19 is a diagram schematically showing an example of the configuration of a combining circuit provided in the entropy encoding circuit in the second embodiment.

FIG. 20 is a diagram schematically showing an example of the configuration of an entropy encoding circuit in the third embodiment.

FIG. 21 is a diagram for explaining an overview of the operation of a compression device according to a fourth embodiment.

FIG. 22 is a flowchart showing an example of the processing procedure of first conversion processing in the fourth embodiment.

FIG. 23 is a flowchart showing an example of the processing procedure for second conversion processing in the fourth embodiment.

### DETAILED DESCRIPTION

An object of one or more embodiments is to provide a compression device, a memory system, and a compression method that can achieve compactness.

In general, according to an embodiment, a compression device is configured to perform dictionary-based coding and entropy coding on first data that is continuously input. The compression device includes a first encoder configured to perform the dictionary-based coding with respect to the first data to generate a first symbol, a first converter configured to convert the first symbol into a plurality of second symbols and cyclically output one of the plurality of second symbols per cycle, a first buffer that stores each of the plurality of second symbols output from the first converter, a generator configured to generate an encoding table for the entropy coding, and a second encoder configured to cyclically read out one of the second symbols from the first buffer per cycle after the encoding table is generated, and perform the entropy coding with respect to a bit sequence comprising the plurality of second symbols with reference to the generated encoding table.

Embodiments will be hereinafter described with reference to the drawings.

### First Embodiment

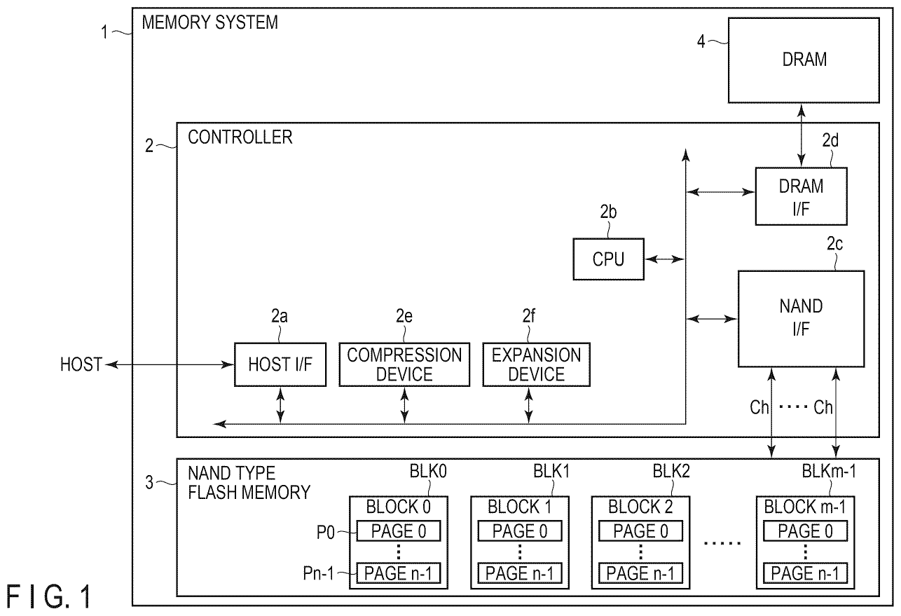

First, a first embodiment will be described. FIG. 1 is a block diagram schematically showing an example of a hardware configuration of a memory system according to the first embodiment.

The memory system 1 shown in FIG. 1 is a semiconductor storage device that is configured to write data into a non-volatile memory and read data from the non-volatile memory. This memory system 1 can be implemented, for example, in the form of a solid state drive (SSD).

The memory system 1 is configured to be connectable to a host via a system bus such as a PCI Express bus. As shown in FIG. 1, the memory system 1 includes a controller 2, a NAND type flash memory 3, and a dynamic random access memory (DRAM) 4.

The controller 2 has a function of controlling the operation of the memory system 1. The controller 2 includes a host interface (I/F) 2a, a CPU 2b, a NAND interface (I/F) 2c, a DRAM interface (I/F) 2d, or the like. It is noted that the host interface 2a, the CPU 2b, the NAND interface 2c, and the DRAM interface 2d are connected to one another, for example, via a bus.

The host interface 2a is a host interface circuit that is configured to communicate with a host located outside the memory system 1. This host interface 2a may be, for example, a PCI Express controller or the like. The host interface 2a receives various commands (requests) from the host.

The CPU 2b is a processor that is configured to control the host interface 2a, the NAND interface 2c, the DRAM interface 2d, or the like. In response to power-on of the memory system 1, the CPU 2b loads a control program (firmware) from the NAND type flash memory 3 or a read only memory (ROM) (not shown) into the DRAM 4, and executes the control program to perform various processing. Specifically, the CPU 2b executes processing for various commands issued by the host. It is noted that some or all of the processing for commands issued by the host may be executed by dedicated hardware in the controller 2.

The NAND interface 2c is a memory control circuit that is configured to control the NAND type flash memory 3 under the control of the CPU 2b.

Furthermore, the controller 2 includes a compression device (compressor) 2e and an expansion device (expander) 2f.

For example, when a write command is issued from the host, the compression device 2e inputs data specified in the write command, and compresses the data by converting the data into a code (i.e., encoding the data). It is noted that in the present embodiment, the data is compressed using an encoding method (compression method) in which dictionary-based coding and entropy coding are combined with each other.

The CPU 2b writes the data compressed in the compression device 2e into the NAND type flash memory 3 via the NAND interface 2c. It is noted that the data to be written into the NAND type flash memory 3 may have undergone predetermined processing such as error correction processing or randomization processing. In other words, the CPU 2b writes data based on the data compressed in the compression device 2e into the NAND type flash memory 3.

For example, when a read command is received from the host via the host interface 2a, the CPU 2b reads data based on the read command from the NAND type flash memory 3 via the NAND interface 2c. When the read data is data compressed in the compression device 2e as described above, the data is input to the expansion device 2f by the CPU 2b. It is noted that the data read out from the NAND type flash memory 3 may be subjected to predetermined processing such as error correction processing or randomization cancellation processing before being input to the expansion device 2f. The expansion device 2f operates to expand the input data. In other words, the CPU 2b causes the expansion device 2f to expand the compressed data based on the data read out from the NAND type flash memory 3 to generate expanded data.

The NAND type flash memory 3 is a non-volatile memory, and has a memory cell array including a plurality of memory cells arranged in a matrix form. The NAND type flash memory 3 may be a NAND type flash memory having a two-dimensional structure or a NAND type flash memory having a three-dimensional structure.

The memory cell array of the NAND type flash memory 3 includes a plurality of blocks BLK0 to BLKm-1. Each of the blocks BLK0 to BLKm-1 consists of a number of pages (in this case, pages P0 to Pn-1). The blocks BLK0 to BLKm-1 function as erase units. Each of the pages P0 to Pn-1 includes a plurality of memory cells connected to the same word line. The pages P0 to Pn-1 are units for a data writing operation and a data reading operation.

In this case, the memory system 1 has been described as having a NAND type flash memory 3, but the memory system 1 may also be configured to have a non-volatile memory such as a phase change memory (PCM) or a magnetoresistive random access memory (MRAM).

The DRAM 4 is a volatile memory, and functions as, for example, a temporary buffer or the like for software to be executed in the controller 2 (CPU 2b) or a temporary buffer or the like for the NAND type flash memory 3.

It is noted that FIG. 1 shows that the memory system 1 has the NAND type flash memory 3 and the DRAM 4, however, the memory system 1 is assumed to further have a volatile memory (not shown) such as a static random access memory (SRAM) inside the controller 2.

Furthermore, in FIG. 1, the compression device 2e and the expansion device 2f are described as being incorporated in the controller 2, but one or both of the compression device 2e and the expansion device 2f may be provided outside the memory system 1 or the controller 2.

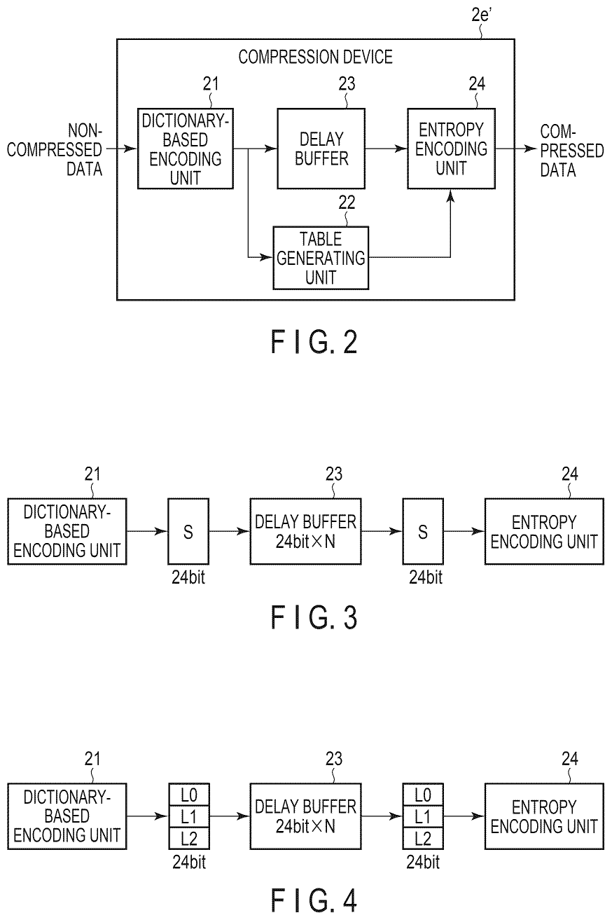

Here, an example of the configuration of a compression device according to a comparative example of the present embodiment will be described with reference to FIG. 2. It is noted that in the present embodiment, it has been described that data is compressed using the encoding method in which the dictionary-based coding and the entropy coding are combined with each other, but in the comparative example of the present embodiment, data is compressed using a similar encoding method.

As shown in FIG. 2, a compression device 2e′ according to the comparative example of the present embodiment includes a dictionary-based encoding unit 21, a table generating unit 22, a delay buffer 23, and an entropy encoding unit 24.

The dictionary-based encoding unit 21 sequentially performs dictionary-based coding (dictionary compression) on data (hereinafter referred to as non-compressed data) that is continuously input to the compression device 2e′. It is noted that the dictionary-based coding is an encoding method for converting (replacing) (at least a part of) non-compressed data into a relative reference to non-compressed data (hereinafter referred to as past data) that was input before (i.e., in the past) the non-compressed data.

Specifically, the dictionary-based encoding unit 21 has a buffer (hereinafter referred to as dictionary buffer) that stores past data, and searches the dictionary buffer for past data that matches the non-compressed data.

When past data that matches at least a portion of the non-compressed data exists in the dictionary buffer, a set of information indicating the length of a matched portion between the non-compressed data and the past data existing in the dictionary buffer (hereinafter referred to as the match length) and information indicating a location in the dictionary buffer where the past data matching the portion of the non-compressed data is stored (hereinafter referred to as the match distance) can be obtained as a dictionary-based coding result. It is noted that the set of match length and match distance corresponds to a pointer to the past data that matches the portion of the non-compressed data.

On the other hand, when past data matching any portion of the non-compressed data does not exist in the dictionary buffer, the non-compressed data cannot be replaced with the above-mentioned pointer (match length and match distance). In this case, the dictionary-based coding result becomes information indicating the non-compressed data (hereinafter, referred to as literal).

The dictionary-based coding result described above is called a symbol. Specifically, a symbol including a match length and a match distance is called a dictionary match symbol, and a literal (i.e., data that has not been replaced with a pointer) is called a dictionary mismatch symbol. In other words, the dictionary-based encoding unit 21 performs the dictionary-based coding on non-compressed data to generate two types of symbols (a dictionary match symbol and a dictionary mismatch symbol). The symbols generated by the dictionary-based encoding unit 21 in this way are output to the table generating unit 22.

The table generating unit 22 generates an encoding table to be used for performing entropy coding. Here, the entropy coding is an encoding technique for converting each of the above-mentioned symbols into a codeword (i.e., a variable-length code) whose code length corresponds to the frequency of appearance of the symbol. The entropy coding uses the difference in the frequency of appearance of a symbol to assign a variable-length code to the symbol, whereby it is possible to reduce the overall amount of data.

The table generating unit 22 receives a symbol which is output from the dictionary-based encoding unit 21 each time the dictionary-based coding is performed on non-compressed data, and counts the frequency of appearance of the symbol. The table generating unit 22 generates an encoding table in which the variable-length code to be assigned to the symbol is defined according to the counted frequency of appearance of the symbol.

Here, the entropy coding described above is performed on the symbols output from the dictionary-based encoding unit 21. The encoding table to be used for performing the entropy coding is generated by counting the frequency of appearance of symbols which are sequentially output from the dictionary-based encoding unit 21. Therefore, the compression device 2e′ needs a mechanism for holding symbols to be subjected to the entropy coding (symbols output from the dictionary-based encoding unit 21) until the encoding table is generated.

For this reason, the symbols generated by the dictionary-based encoding unit 21 are output from the dictionary-based encoding unit 21 to the delay buffer 23, and stored in the delay buffer 23. It is noted that the delay buffer 23 is implemented, for example, by an SRAM in the controller 2.

When the encoding table is generated by the table generating unit 22, the entropy encoding unit 24 reads out symbols from the delay buffer 23, and refers to the encoding table to perform the entropy coding. In the entropy coding, a variable-length code defined in the encoding table is assigned to each of the symbols read out from the delay buffer 23 according to the frequency of appearance of the symbol.

The compression device 2e′ according to the comparative example of the present embodiment outputs data (hereinafter referred to as compressed data) including the variable-length code assigned to each symbol as described above (i.e., an entropy coding result).

It is noted that as described above, the non-compressed data is compressed by sequentially performing the dictionary-based coding and the entropy coding, and thus the compressed data is expanded by sequentially performing entropy decoding and dictionary-based decoding. In other words, the expansion device 2f operates to output non-compressed data by performing the entropy decoding and the dictionary-based decoding on input compressed data.

For example, when continuously input non-compressed data are character string data in which one character is represented by 1 byte, and the match length included in the dictionary match symbol is assumed to include 256 bytes (256 characters) at maximum, the match length is expressed by 8 bits. Furthermore, when the match distance included in the dictionary match symbol is assumed to include 64 KiB at maximum, the match distance is expressed by 16 bits. On the other hand, when the non-compressed data is data representing 1 character, the literal included in the dictionary mismatch symbol is expressed by 8 bits.

In other words, the delay buffer 23 stores a dictionary match symbol of 24-bit size including a match length (8 bits) and a match distance (16 bits) and a dictionary mismatch symbol of 8-bit size including a literal (8 bits) by sequentially performing the dictionary-based coding on the non-compressed data.

It is noted that the dictionary-based coding is performed according to a processing unit called a cycle, for example. In other words, dictionary match symbols and dictionary mismatch symbols are output from the dictionary-based encoding unit 21 to the delay buffer 23 in each cycle.

In this case, as shown in FIG. 3, the width (corresponding to bit width of data in a single word line of the delay buffer 23 which is an access unit of the delay buffer 23) of the delay buffer 23 implemented, for example, by an SRAM is set to 24 bits so as to match a dictionary match symbol S which has a larger size (amount of data) among the symbols output from the dictionary-based encoding unit 21. This makes it possible to efficiently process symbols resulting from the dictionary-based coding.

Since the size of the dictionary mismatch symbol is 8 bits, as shown in FIG. 4, for example, the dictionary mismatch symbols may be stored in the delay buffer 23 with three dictionary mismatch symbols L0 to L2 (24 bits) being set as a unit. In this case, the dictionary mismatch symbols L0 to L2 are temporarily stored, for example, in a write buffer or the like, and output to the delay buffer 23.

When the entropy coding is performed, the three dictionary mismatch symbols L0 to L2 are read out from the delay buffer 23. However, the three dictionary mismatch symbols L0 to L2 are temporarily stored in a read buffer or the like, and then delivered one by one from the read buffer to the entropy encoding unit 24.

It is noted that “24 bits×N” in FIGS. 3 and 4 indicates that the width (i.e., the number of columns) of the delay buffer 23 (SRAM) is 24 bits, and a word line number (i.e., the number of rows) of the delay buffer 23 is N.

In the comparative example of the present embodiment, for example, the width of the delay buffer 23 is set to 24 bits because it is assumed that a dictionary match symbol (24 bits) is stored in the delay buffer 23 in one cycle. However, an increase in the width of the delay buffer 23 causes an increase in the area of the delay buffer 23, which causes a decrease in the area efficiency of the compression device 2e′.

To address sicu an issue, in the present embodiment, a mechanism for making it possible to enhance the area efficiency of the compression device 2e that adopts an encoding method (compression method) including entropy coding as described above will be described.

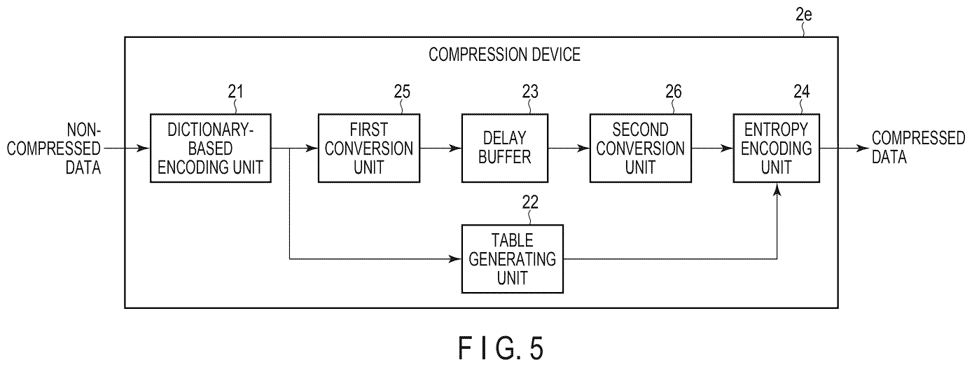

FIG. 5 shows an example of the configuration of the compression device 2e according to the present embodiment. It is noted that in FIG. 5, the same reference signs are appended to similar portions to those in FIG. 2 described above, and detailed descriptions thereof will be omitted. Here, different portions from those in FIG. 2 will be described.

As shown in FIG. 5, the compression device 2e according to the present embodiment further includes a first conversion unit 25 and a second conversion unit 26 in addition to the dictionary-based encoding unit 21, the table generating unit 22, the delay buffer 23, and the entropy encoding unit 24 shown in FIG. 2.

The first conversion unit 25 and the second conversion unit 26 are arranged before and after, respectively, the delay buffer 23 so as to sandwich the delay buffer 23 therebetween.

The first conversion unit 25 inputs the dictionary match symbol output from the dictionary-based encoding unit 21 as described in the comparative example of the present embodiment described above. The first conversion unit 25 converts the input dictionary match symbol into a plurality of symbols (hereinafter, referred to as sub-symbols). The plurality of sub-symbols converted from the dictionary match symbol by the first conversion unit 25 are respectively output to the delay buffer 23 in different cycles. It is noted that the first conversion unit 25 executes processing for generating a plurality of sub-symbols by dividing a dictionary match symbol. It is noted that in the following description, the conversion processing to be executed by the first conversion unit 25 is referred to as first conversion processing.

The second conversion unit 26 reads out (takes out) the plurality of sub-symbols from the delay buffer 23 in different cycles, respectively. The second conversion unit 26 converts the plurality of sub-symbols read out from the delay buffer 23 into a dictionary match symbol. In other words, the second conversion unit 26 executes processing for returning the plurality of sub-symbols read out from the delay buffer 23 to a dictionary match symbol before the dictionary match symbol is converted into the plurality of sub-symbols by the first conversion unit 25. It is noted that in the following description, the conversion processing to be executed by the second conversion unit 26 is referred to as second conversion processing.

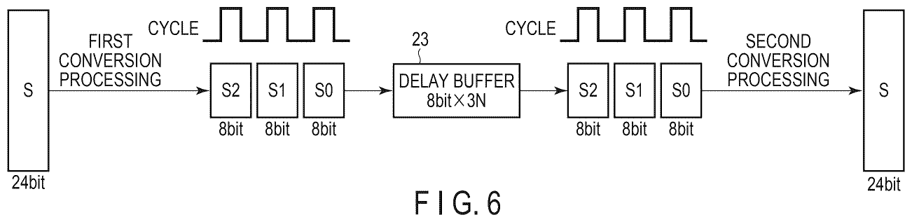

Here, an overview of the operation of the compression device 2e according to the present embodiment will be described with reference to FIG. 6.

First, FIG. 6 shows that the 24-bit dictionary match symbol S output from the dictionary-based encoding unit 21 is converted (divided) into three sub-symbols S0 to S2, each having 8 bits, by the first conversion processing.

The three sub-symbols S0 to S2 converted from the dictionary match symbol S in this way are output to the delay buffer 23 in different cycles, and stored in the delay buffer 23.

In the comparative example of the present embodiment described above, it has been described that the delay buffer 23 having a width for data of 24 bits is used. However, in the present embodiment, the dictionary match symbol S (24 bits) is converted into three sub-symbols S0 to S2 (8 bits) as described above, which makes it possible to use a delay buffer 23 (SRAM) having a width for data of 8 bits.

It is noted that as shown in FIG. 6, the word line number of the delay buffer 23 used in the present embodiment is 3N. Therefore, the delay buffer 23 used in the present embodiment has a smaller width than the delay buffer 23 used in the comparative example of the present embodiment, but has the same capacity.

When the sub-symbols S0 to S2 converted from the dictionary match symbol S are stored in the respective word lines of the delay buffer 23 as described above, the sub-symbols S0 to S2 are read out from the respective word lines of the delay buffer 23 in different cycles. The sub-symbols S0 to S2 thus read out from the delay buffer 23 are converted (e.g., merged) into the dictionary match symbol S by the second conversion processing.

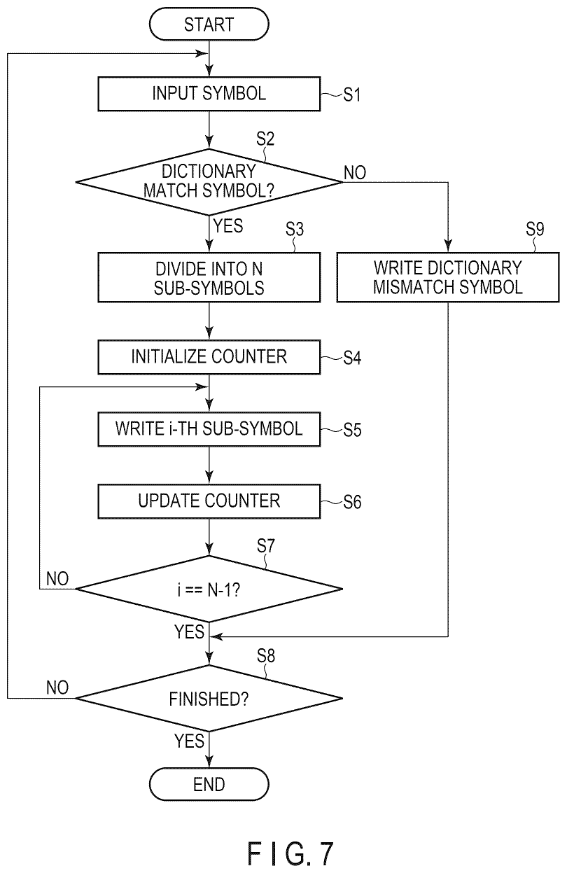

Next, an example of the processing procedure of the first conversion processing in the present embodiment will be described with reference to the flowchart in FIG. 7.

First, the first conversion unit 25 inputs (receives) a symbol (generated symbol) output from the dictionary-based encoding unit 21 (step S1). Hereinafter, the symbol input in step S1 is referred to as an input symbol.

Here, the dictionary-based encoding unit 21 operates to output a dictionary match symbol (match length and match distance) or a dictionary mismatch symbol (literal) according to non-compressed data as described above. For this reason, the first conversion unit 25 determines whether the input symbol is a dictionary match symbol (step S2).

When it is determined that the input symbol is a dictionary match symbol (YES in step S2), the first conversion unit 25 divides the dictionary match symbol into N (N represents an integer equal to 2 or more) sub-symbols (step S3). The processing in step S3 corresponds to the processing for converting a dictionary match symbol into a plurality of sub-symbols.

The first conversion unit 25 has a counter, and initializes the counter (step S4). In this case, a counter value i is set to 0 (i=0).

Then, the first conversion unit 25 writes an i-th sub-symbol of the N sub-symbols in an i-th cycle into the delay buffer 23 based on the counter value i (step S5).

When the processing of step S5 is executed, the first conversion unit 25 updates the counter (step S6). In this case, the counter value i is set to i+1 (i=i+1).

The first conversion unit 25 determines whether the counter value i matches N-1 (i=N−1) (step S7).

When it is determined that the counter value i does not match N-1 (NO in step S7), the processing returns to step S5 to repeat the processing. By repeating the processing as described above, the first conversion unit 25 can sequentially write (output) the N sub-symbols converted from the dictionary match symbol in step S3 into the delay buffer 23 in different cycles.

On the other hand, when it is determined that the counter value i matches N-1 (YES in step S7), it is determined whether the first conversion processing is terminated (step S8). When the input symbol is not a final symbol (a symbol generated from the last non-compressed data), but a symbol which is further output from the dictionary-based encoding unit 21, it is determined in step S8 that the first conversion processing is not terminated. On the other hand, when the input symbol is a final symbol and there is no non-compressed data to be compressed in the compression device 2e, it is determined in step S8 that the first conversion processing is terminated.

When it is determined that the first conversion processing is not terminated (NO in step S8), the processing returns to step S1 to repeat the processing.

On the other hand, when it is determined that the first conversion processing is terminated (YES in step S8), the first conversion processing shown in FIG. 7 is terminated.

It is noted that when it is determined that the input symbol is not a dictionary match symbol (i.e., a dictionary mismatch symbol) (NO in step S2), the first conversion unit 25 writes the dictionary mismatch symbol into the delay buffer 23 (step S9). When the processing of step S9 is executed, the processing of step S8 is executed.

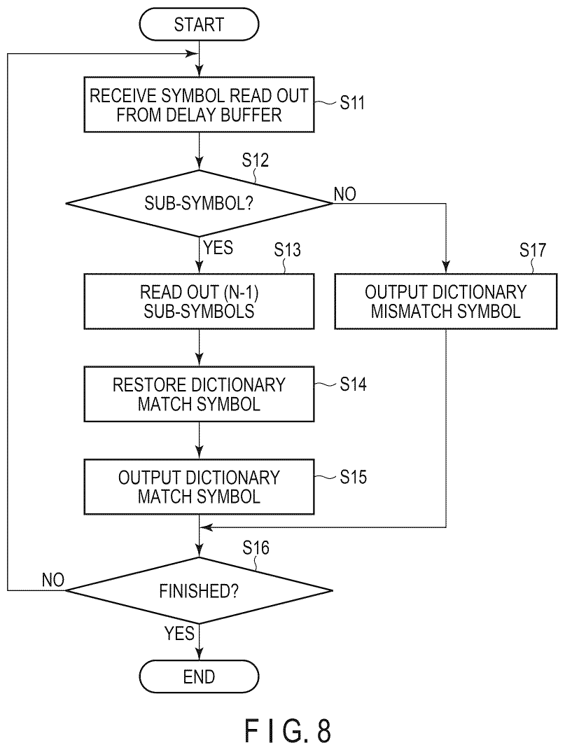

Next, an example of the processing procedure of the second conversion processing in the present embodiment will be described with reference to the flowchart in FIG. 8.

First, the second conversion unit 26 inputs (receives) a symbol (data) read out from the delay buffer 23 (step S11). Hereinafter, the symbol input in step S11 is referred to as an input symbol.

According to the first conversion processing described above, a plurality of sub-symbols converted from a dictionary match symbol and a dictionary mismatch symbol are stored (written) in the delay buffer 23. Therefore, the second conversion unit 26 determines whether the input symbol is a sub-symbol (step S12).

Assuming that the dictionary match symbol has been converted into N sub-symbols as described above, when it is determined that the input symbol is a sub-symbol (YES in step S12), the second conversion unit 26 further reads out, from the delay buffer 23, (N-1) sub-symbols written in the delay buffer 23 subsequently to the symbol (step S13).

Next, the second conversion unit 26 concatenates the input symbol (here, the sub-symbol) and the (N-1) sub-symbols read out from the delay buffer 23 in step S13 to restore the dictionary match symbol (step S14). The processing in step S14 corresponds to the processing for converting a plurality of sub-symbols into a dictionary match symbol.

When the processing of step S14 is executed, the second conversion unit 26 outputs the dictionary match symbol restored in step S14 to the entropy encoding unit 24 (step S15).

Next, it is determined whether the second conversion processing is terminated (step S16). When the final symbol has not been read out from the delay buffer 23, it is determined in step S16 that the second conversion processing is not terminated. On the other hand, when the final symbol has been read out from the delay buffer 23, it is determined in step S16 that the second conversion processing is terminated.

When it is determined that the second conversion processing is not terminated (NO in step S16), the processing returns to step S11 to repeat the processing.

On the other hand, when it is determined that the second conversion processing is terminated (YES in step S16), the second conversion processing shown in FIG. 8 is terminated.

It is noted that when it is determined that the input symbol is not a sub-symbol (i.e., a dictionary mismatch symbol) (NO in step S12), the second conversion unit 26 outputs the dictionary mismatch symbol to the entropy encoding unit 24 (step S17). When the processing of step S17 is executed, the processing of step S16 is executed.

The table generating unit 22 in the present embodiment counts the frequency of appearance of symbols (dictionary match symbols and dictionary mismatch symbols output from the dictionary-based encoding unit 21) generated by performing the dictionary-based coding in the same manner as in the comparative example of the present embodiment described above, and generates an encoding table in which variable length codes to be assigned to the symbols are defined according to the frequency of appearance of the symbols. Furthermore, when an encoding table is generated by the table generating unit 22 in this manner, the entropy encoding unit 24 in the present embodiment refers to the encoding table and executes processing of assigning variable length codes to the symbols (dictionary match symbols and dictionary mismatch symbols) output from the second conversion unit 26 (i.e., performing entropy coding).

As described above, the compression device 2e according to the present embodiment is configured to perform dictionary-based coding and entropy coding on continuously input non-compressed data, and generates a dictionary match symbol (first symbol) by performing the dictionary-based coding on non-compressed data, and converts the dictionary match symbol into a plurality of sub-symbols (second symbols). Furthermore, the compression device 2e according to the present embodiment includes a delay buffer 23 (first buffer) for storing a plurality of sub-symbols until an encoding table to be used for performing the entropy coding is generated, and when the encoding table is generated, the compression device 2e reads out a plurality of sub-symbols from the delay buffer 23, and refers to the encoding table to perform the entropy coding.

It is noted that the plurality of sub-symbols converted from the dictionary match symbol are respectively output to the delay buffer 23 in different cycles, and read out from the delay buffer 23 in different cycles. The plurality of sub-symbols read out from the delay buffer 23 are converted into a dictionary match symbol, and in the entropy coding, a variable-length code defined in the encoding table is assigned to the dictionary match symbol.

In the present embodiment, by the configuration of converting a dictionary match symbol into a plurality of sub-symbols as described above, it is possible to use a delay buffer 23 having a width (bit width as an access unit) smaller than the size of the dictionary match symbol. Specifically, when the size of the dictionary match symbol is 24 bits, for example, it is possible to set the width of the delay buffer 23 to 8 bits by converting (dividing) the dictionary match symbol into three sub-symbols each having 8 bits.

For SRAMs having the same capacity, it is possible to reduce the area of the delay buffer 23 by reducing the width thereof. In the present embodiment, as described above, it is made possible to use a delay buffer 23 having a smaller width by converting a dictionary match symbol into a plurality of sub-symbol, whereby the area efficiency of the compression device 2e including the delay buffer 23 can be enhanced (i.e., the compression device 2e can be miniaturized).

It is noted that in the dictionary-based coding, when past data that matches non-compressed data exists in the dictionary buffer, the processing for generating a dictionary match symbol (match length and match distance) from the non-compressed data is executed. However, even when a dictionary match symbol is generated from non-compressed data such as a short character string, the compression efficiency is low. Therefore, a dictionary match symbol is generated from non-compressed data input in at least about three cycles (e.g., 3 bytes).

In this case, when the throughput of receiving non-compressed data (input throughput) is defined as the throughput of the compression device 2e (compression pipeline), as described in the present embodiment, the throughput of the compression device 2e is not reduced even when a dictionary match symbol generated, for example, by performing dictionary-based coding on non-compressed data input in at least three cycles is converted into three sub-symbols and output in different cycles (the dictionary match symbol is divided and output over three cycles).

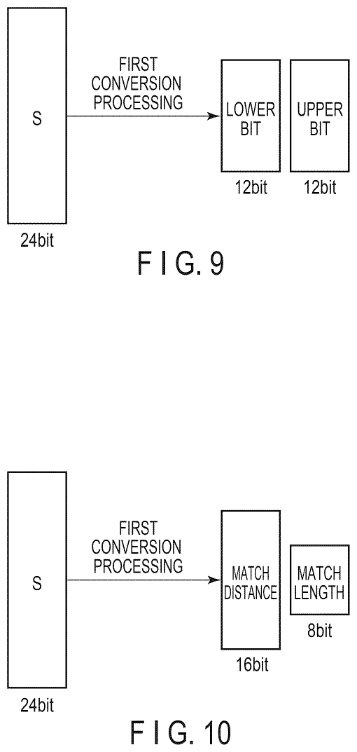

The present embodiment has been described, for example, on the assumption that a dictionary match symbol of 24 bits is converted into three sub-symbols (8 bits), but the number of sub-symbols converted from a dictionary match symbol may be other than three. The size of each of the sub-symbols may be at least smaller than the size of the dictionary match symbol and equal to or smaller than the width of the delay buffer 23. Specifically, as shown in FIG. 9, a dictionary match symbol of 24 bits may be converted into two sub-symbols corresponding to an upper bit and a lower bit, respectively. In this case, a delay buffer 23 having a width for data of 12 bits may be used. Even such a configuration makes it possible to enhance the area efficiency of the compression device 2e as compared with the delay buffer 23 having a width for data of 24 bits described in the comparative example of the present embodiment. Furthermore, the respective sizes of the sub-symbols may not be the same.

It is noted that it is assumed that the dictionary-based encoding unit 21, the table generating unit 22, the entropy encoding unit 24, the first conversion unit 25, and the second conversion unit 26 of the compression device 2e according to the present embodiment are implemented by hardware, but some or all of the units 21, 22, and 24 to 26 may be implemented, for example, by the CPU 2b equipped in the compression device 2e executing a predetermined program (i.e., software). Furthermore, the present embodiment has been described on the assumption that the delay buffer 23 is implemented by an SRAM, but the delay buffer 23 may be implemented by a memory device other than an SRAM.

### Second Embodiment

Next, the second embodiment will be described. It is noted that in this embodiment, detailed descriptions of the parts similar to those of the first embodiment described above will be omitted, and the parts different from the first embodiment will be mainly described. In addition, since the hardware configuration of the memory system according to this embodiment is the same as that of the first embodiment described above, FIG. 1 will be used as appropriate for the description.

The first embodiment has been described above mainly on the assumption that the dictionary match symbol of 24 bits is converted into, for example, three sub-symbols each having 8 bits. However, as shown in FIG. 10, the present embodiment differs from the first embodiment in that the dictionary match symbol S is converted into a sub-symbol (hereinafter referred to as a first sub-symbol) corresponding to a match length (8 bits) included in the dictionary match symbol S and a sub-symbol (hereinafter referred to as a second sub-symbol) corresponding to a match distance (16 bits).

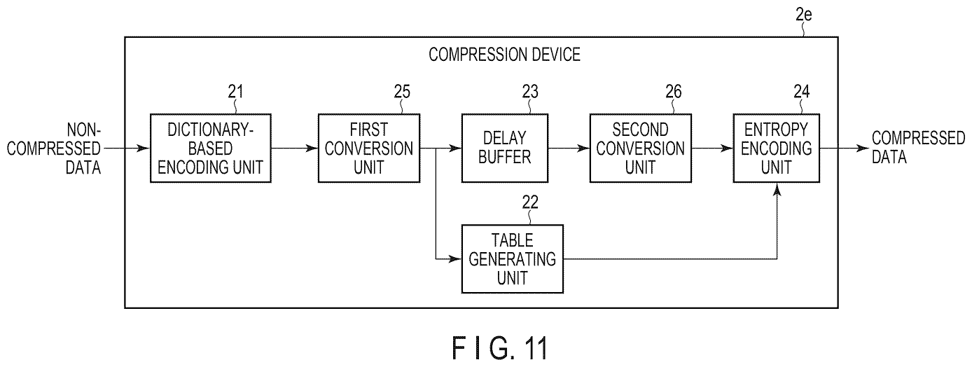

FIG. 11 shows an example of the configuration of a compression device 2e according to the present embodiment. It is noted that in FIG. 11, the same reference signs are appended to similar portions to those in FIG. 5 described above, and detailed description thereof are omitted. Portions different from those in FIG. 5 will be hereunder described.

A first conversion unit 25 in the present embodiment converts a dictionary match symbol into first and second sub-symbols described above. The first and second sub-symbols converted from the dictionary match symbol by the first conversion unit 25 are output to a delay buffer 23 in different cycles.

It is noted that as described with respect to FIG. 10, the first sub-symbol corresponds to the match length (8 bits) included in the dictionary match symbol, and the second sub-symbol corresponds to the match distance (16 bits) included in the dictionary match symbol. Therefore, in the present embodiment, a delay buffer 23 (SRAM) having a width for data of 16 bits is used to match the second sub-symbol having a larger size among sub-symbols output from the first conversion unit 25.

Furthermore, a second conversion unit 26 in the present embodiment converts first and second sub-symbols read out from the delay buffer 23 in different cycles into a dictionary match symbol.

It is noted that the above-mentioned first embodiment has been described on the assumption that a dictionary match symbol output from the dictionary-based encoding unit 21 is input to the table generating unit 22. However, as shown in FIG. 11, it is assumed that the table generating unit 22 in the present embodiment inputs the first and second sub-symbols output from the first conversion unit 25.

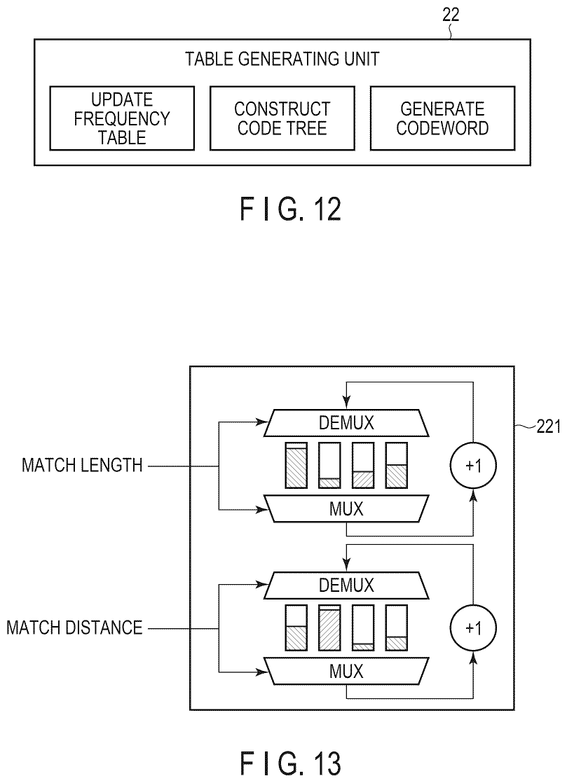

The operation of the table generating unit 22 will be described below with reference to FIG. 12. As shown in FIG. 12, the table generating unit 22 generates an encoding table by sequentially executing processing of updating a frequency table for counting the frequency of appearance of a symbol input to the table generating unit 22, processing of constructing a code tree corresponding to the frequency of appearance of the symbol, processing of generating a variable-length code (codeword) based on the code tree, or the like.

Here, a configuration of a circuit for implementing the update of the frequency table to be executed by the table generating unit 22 described above (hereinafter referred to as a frequency table updating circuit) will be described. It is noted that the frequency table updating circuit includes, for example, a multiplexer (MUX), a counter, a demultiplexer (DEMUX), or the like.

FIG. 13 schematically shows an example of the configuration of the frequency table updating circuit in the first embodiment described above. Since the first embodiment described above is configured such that the dictionary match symbol output from the dictionary-based encoding unit 21 is input to the table generating unit 22, a frequency table updating circuit 221 shown in FIG. 13 is configured to update the frequency of appearance of each of the match length and the match distance included in the dictionary match symbol (i.e., a frequency table) in one cycle.

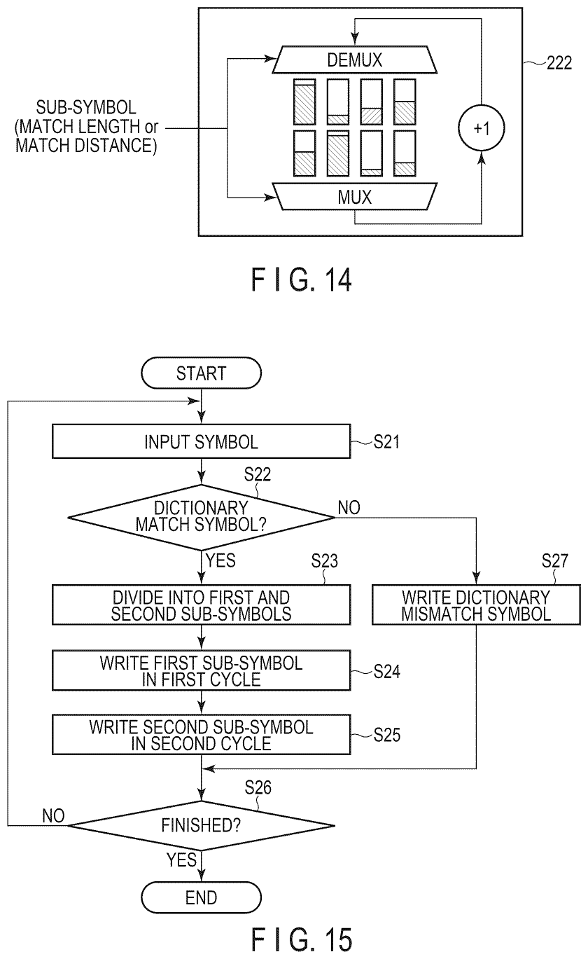

FIG. 14 schematically shows an example of the configuration of a frequency table updating circuit in the present embodiment. The present embodiment is configured such that first and second sub-symbols output from the first conversion unit 25 in different cycles are input to the table generating unit 22. Therefore, a frequency table updating circuit 222 shown in FIG. 14 needs only to be configured to update the frequency of appearance of one sub-symbol (i.e., a frequency table) in one cycle.

Specifically, the frequency table updating circuit 221 shown in FIG. 13 includes two multiplexers, two counters, and two demultiplexers to implement the update of a frequency table for each of a match length and a match distance included in a dictionary match symbol input in one cycle, whereas the frequency table updating circuit 222 shown in FIG. 14 only needs to include one multiplexer, one counter, and one demultiplexer to implement the update of a frequency table for one sub-symbol input in one cycle.

Next, an example of the processing procedure of first conversion processing in the present embodiment will be described with reference to a flowchart in FIG. 15.

First, the processing of steps S21 and S22 corresponding to the processing of steps S1 and S2 shown in FIG. 7 described above are executed.

When an input symbol is determined to be a dictionary match symbol (YES in step S22), the first conversion unit 25 divides (decomposes) the dictionary match symbol into a first sub-symbol (match length portion) and a second sub-symbol (match distance portion) (step S23). The processing of this step S23 corresponds to the processing of converting a dictionary match symbol into first and second sub-symbols.

Next, the first conversion unit 25 writes the first sub-symbol into the delay buffer 23 in a first cycle (step S24).

When the processing of step S24 has been executed, the first conversion unit 25 writes the second sub-symbol into the delay buffer 23 in a second cycle subsequently to the first cycle (step S25).

According to the above-mentioned processing of steps S24 and S25, first and second sub-symbols converted from a dictionary match symbol in step S23 are sequentially written (output) into the delay buffer 23 in different cycles. It is noted that the first and second sub-symbols are also output to the table generating unit 22 in different cycles.

When the processing of step S25 is executed, the processing of step S26 which corresponds to the processing of step S8 shown in FIG. 7 described above is executed.

It is noted that when it is determined that the input symbol is not a dictionary match symbol (NO in step S22), the processing of step S27 which corresponds to the processing of step S9 shown in FIG. 7 described above is executed.

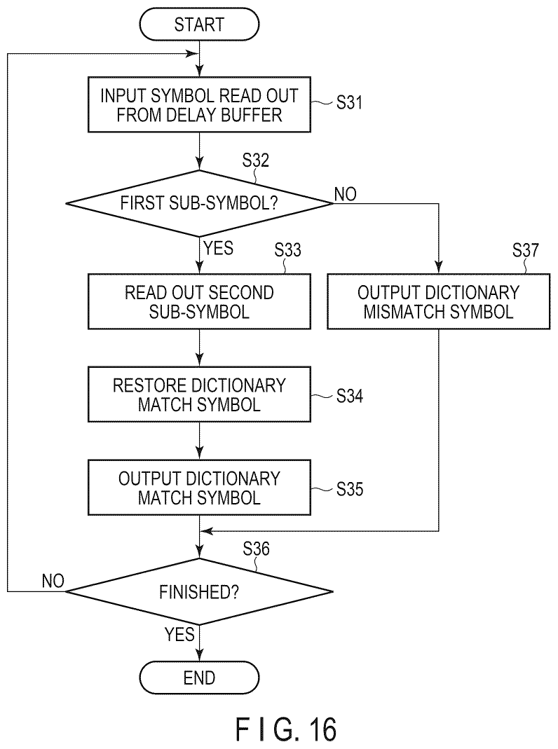

Next, an example of the processing procedure of the second conversion processing in the present embodiment will be described with reference to a flowchart in FIG. 16.

First, the processing of step S31 which corresponds to the processing of step S11 shown in FIG. 8 described above is executed.

Here, according to the first conversion processing described above, first and second sub-symbols converted from a dictionary match symbol and a dictionary mismatch symbol are stored (written) in the delay buffer 23. Therefore, the second conversion unit 26 determines whether the input symbol is the first sub-symbol (step S32).

When it is determined that the input symbol is the first sub-symbol (YES in step S32), the second conversion unit 26 further reads out the second sub-symbol written to the delay buffer 23 subsequently to the first sub-symbol from the delay buffer 23 (step S33).

Next, the second conversion unit 26 concatenates the input symbol (here, the first sub-symbol) and the second sub-symbol read from the delay buffer 23 in step S33 to restore the dictionary match symbol (step S34). The processing of step S34 corresponds to the processing of converting the first and second sub-symbols into the dictionary match symbol.

When the processing of step S34 is executed, the processing of steps S35 and S36 corresponding to the processing of steps S15 and S16 shown in FIG. 8 described above is executed.

It is noted that when it is determined that the input symbol is not the first sub-symbol (i.e., it is determined as a dictionary mismatch symbol) (NO in step S32), the processing of step S37 corresponding to the processing of step S17 shown in FIG. 8 described above is executed.

As described above, the compression device 2e according to the present embodiment converts a dictionary match symbol into a plurality of sub-symbols each including a first sub-symbol (second symbol) containing a match length and a second sub-symbol (second symbol) containing a match distance.

In the present embodiment, as in the first embodiment described above, such a configuration allows the use of a delay buffer 23 having a width smaller than the size of the dictionary match symbol, so that it is possible to enhance the area efficiency of the compression device 2e.

Furthermore, in the present embodiment, since the first sub-symbol (match length portion) and the second sub-symbol (match distance portion) are output from the first conversion unit 25 to the table generating unit 22 in different cycles (i.e., the dictionary match symbol is subjected to time-division) as described above, it is possible to adopt a configuration of counting the frequency of appearance of one sub-symbol in one cycle (i.e., an updating target of the frequency table per cycle is one symbol) as in the frequency table updating circuit 222 shown in FIG. 14.

In other words, according to the frequency table updating circuit 222 in the present embodiment, it is possible to reduce the numbers of multiplexers, demultiplexers, and counters (i.e., the circuit scale is reduced) as compared with the frequency table updating circuit 221 in the first embodiment described above, which can contribute to the miniaturization of the compression device 2e.

### Third Embodiment

Next, a third embodiment will be described. It is noted that in the present embodiment, detailed description of similar portions to those of the second embodiment described above will be omitted, and different portions from those of the second embodiment will be mainly described. Furthermore, as in the second embodiment described above, the hardware configuration of a memory system according to the present embodiment will be described using FIG. 1 as appropriate.

The second embodiment has been described above on the assumption that the first and second sub-symbols are converted to the dictionary match symbol before the entropy coding is performed. However, the present embodiment differs from the second embodiment in that this conversion is not performed.

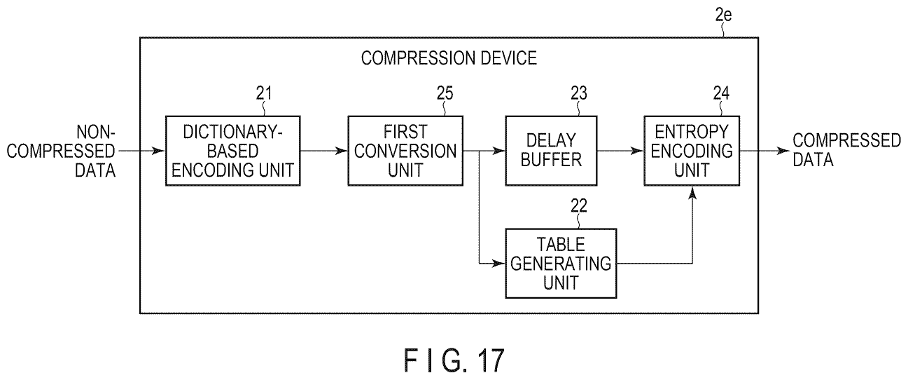

FIG. 17 shows an example of the configuration of a compression device 2e according to the present embodiment. It is noted that in FIG. 17, the same reference signs are appended to portions similar to those in FIG. 11 described above, and detailed description thereof will be omitted. Here, different portions from those in FIG. 11 will be described.

As shown in FIG. 17, the compression device 2e according to the present embodiment does not include the second conversion unit 26 unlike the second embodiment described above.

In this case, in the second embodiment described above, the dictionary match symbol converted (restored) from the first and second sub-symbols by the second conversion unit 26 is input to the entropy encoding unit 24, whereas in the present embodiment, the first and second sub-symbols read out from the delay buffer 23 in different cycles are input to the entropy encoding unit 24.

A configuration of a circuit (hereinafter, referred to as an entropy encoding circuit) for implementing entropy coding to be performed by the entropy encoding unit 24 will be hereunder described. It is noted that the entropy encoding circuit includes, for example, a multiplexer (MUX), or the like, and operates to perform the entropy coding by referring to an encoding table generated by the table generating unit 22.

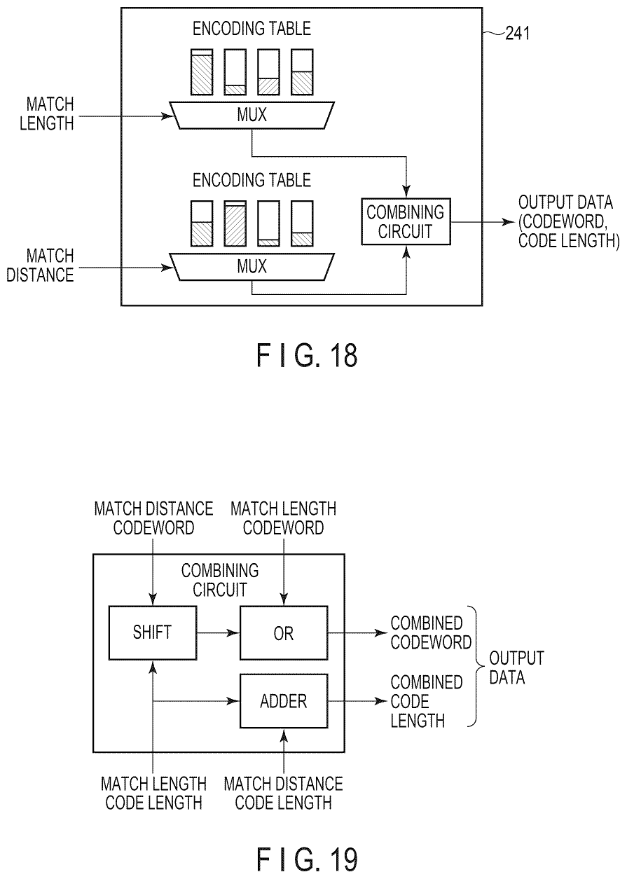

Here, FIG. 18 schematically shows an example of the configuration of the entropy encoding circuit in the second embodiment described above.

As described in the second embodiment, when a dictionary match symbol is input to the entropy encoding unit 24, the entropy encoding circuit 241 shown in FIG. 18 has two multiplexers each for implementing entropy coding for each of a match length and a match distance included in the dictionary match symbol, and operates to assign variable-length codes to both the match length and the match distance. In this case, a variable-length code (a match length codeword and a match length code length) assigned to the match length is output to the multiplexer corresponding to the match length, and a variable-length code (a match distance codeword and a match distance code length) assigned to the match distance is output to the multiplexer corresponding to the match distance.

It is noted that the entropy encoding circuit 241 includes a combining circuit, and the variable-length codes output from the two multiplexers are input to the combining circuit. Although detailed description is omitted, the combining circuit operates to combine the variable-length codes input to the combining circuit. For example, as shown in FIG. 19, the combining circuit includes a shift circuit for implementing bit shifting of the match distance codeword corresponding to the match length code length in order to appropriately combine the match length codeword and the match distance codeword, an OR circuit for inputting the match length codeword and the output of the shift circuit and outputting a combined codeword, and an adder circuit for inputting the match length code length and the match distance code length and outputting a combined code length. The combined codeword and the combined code length (output data) output from such a combining circuit correspond to the variable-length code (i.e., compressed data) to be assigned to the dictionary match symbol.

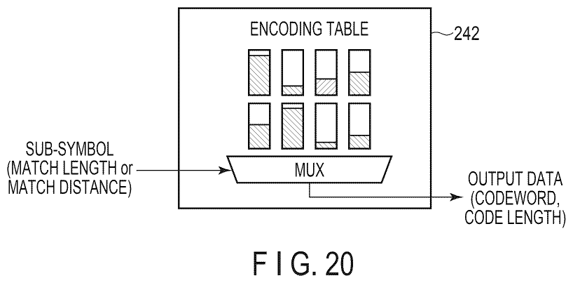

FIG. 20 schematically shows an example of the configuration of an entropy encoding circuit in the present embodiment.

The present embodiment is configured such that the first and second sub-symbols read out from the delay buffer 23 in different cycles are input to the entropy encoding unit 24. Therefore, the entropy encoding circuit 242 shown in FIG. 20 only needs to be configured to be able to assign a variable-length code (codeword and code length) to one sub-symbol in one cycle.

Specifically, the entropy encoding circuit 241 shown in FIG. 18 has two multiplexers and a combining circuit to implement entropy coding for each of the match length and the match distance included in the dictionary match symbol input in one cycle. However, the entropy encoding circuit 242 shown in FIG. 20 only needs to have one multiplexer corresponding to one sub-symbol input in one cycle, and it is unnecessary to provide the entropy encoding circuit 242 with a combining circuit.

It is noted that although not shown, when a dictionary mismatch symbol read out from the delay buffer 23 is input to the entropy encoding unit 24, the entropy encoding unit 24 may operate to output a variable-length code assigned to the dictionary mismatch symbol by referring to the encoding table as in the second embodiment described above.

As described above, the compression device 2e according to the present embodiment performs the entropy coding on each of first and second sub-symbols read out from the delay buffer 23 in different cycles without converting the first and second sub-symbols read out from the delay buffer 23 into a dictionary match symbol (restoring a dictionary match symbol from the first and second sub-symbols). In other words, in the present embodiment, the entropy encoding unit 24 operates to encode the match length and the match distance included in the dictionary match symbol in different cycles.

In the present embodiment, such a configuration makes it possible to omit the second conversion unit 26 as compared with the second embodiment described above, and therefore it is possible to miniaturize the compression device 2e.

Furthermore, according to the entropy encoding circuit 242 in the present embodiment, as compared with the entropy encoding circuit 241 in the second embodiment described above, it is possible to reduce the number of multiplexers and omit the combining circuit (i.e., reduce the circuit scale), which makes it possible to implement further miniaturization of the compression device 2e.

In other words, in the first and second embodiments described above, it has been described that a plurality of sub-symbols converted from a dictionary match symbol are converted (restored) back to the dictionary match symbol. However, in order to implement the miniaturization of the compression device 2e described above, a configuration in which a plurality of sub-symbols are not converted to a dictionary match symbol may be adopted (i.e., the second conversion unit 26 may be omitted).

### Fourth Embodiment

Next, a fourth embodiment will be described. It is noted that in the present embodiment, detailed description of similar portions to those in the second embodiment described above will be omitted, and portions different from those in the second embodiment will be mainly described. Furthermore, with respect to a hardware configuration of a memory system according to the present embodiment, it will be described with reference to FIG. 1 as appropriate as in the second embodiment.

The second embodiment has been described above on the assumption that a dictionary match symbol is converted into a first sub-symbol including a match length and a second sub-symbol including a match distance. However, the present embodiment differs from the second embodiment in that the dictionary match symbol is converted into a plurality of sub-symbols different from those in the second embodiment.

A configuration of a compression device according to the present embodiment will be described hereunder. It is noted that, for convenience, the description will be made using FIG. 11.

As described above, the dictionary match symbol includes a match length and a match distance, but according to a compression method called deflate (deflate standard), each of the match length and the match distance can be represented by a Code section and an Extra section, for example. In this case, the first conversion unit 25 in the present embodiment converts a dictionary match symbol into a Code section (hereinafter referred to as a first Code section) and an Extra section (hereinafter referred to as a first Extra section) that represent a match length, and a Code section (hereinafter referred to as a second Code section) and an Extra section (hereinafter referred to as a second Extra section) that represent a match distance.

Furthermore, the first conversion unit 25 generates a plurality of sub-symbols based on the first Code section, the first Extra section, the second Code section, and the second Extra section converted from the dictionary match symbol as described above. The plurality of sub-symbols generated by the first conversion unit 25 are output to the delay buffer 23 in different cycles.

The second conversion unit 26 in the present embodiment converts the plurality of sub-symbols read out from the delay buffer 23 in different cycles into the first Code section, the first Extra section, the second Code section, and the second Extra section.

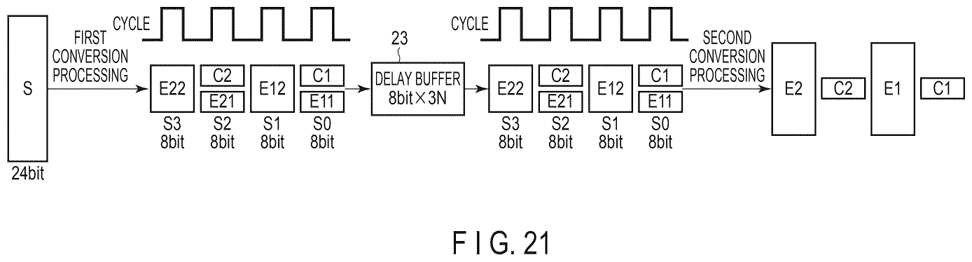

Here, an overview of the operation of the compression device 2e according to the present embodiment will be described with reference to FIG. 21.

First, it is assumed in FIG. 21 that a 24-bit dictionary match symbol S output from the dictionary-based encoding unit 21 is converted into a first Code section C1, a first Extra section E1, a second Code section C2, and a second Extra section E2 by first conversion processing.

It is noted that according to the above-mentioned deflate standard, when a match length ranges from 3 to 10, the match length is represented by a first Code section C1 having a value of 0 to 7. It is noted that in this case, the first Extra section E1 is not used to represent the match length. Furthermore, when a match length ranges from 11 to 18, the match length is represented by a first Code section C1 having a value of 8 to 11 and a first Extra section E1 of 1 bit. Furthermore, when a match length ranges from 12 to 15, the match length is represented by a first Code section C1 having a value of 12 to 15 and a first Extra section E1 of 2 bits.

Detailed description will be omitted, but when a match length is 16 or more, the match length can be likewise represented by a first Code section C1 and a first Extra section E1, and as the match length increases, the size of the first Extra section E1 increases (i.e., the number of bits increases).

The match length has been described above, but the match distance is also represented by a second Code section C2 and a second Extra section E2 in the same way.

In an example shown in FIG. 21, for example, a delay buffer 23 having a width for data of 8 bits is used according to the size (8 bits) of the dictionary mismatch symbol, and the first conversion unit 25 generates a plurality of sub-symbols each having a size of 8 bits from the above-mentioned first Code section C1, first Extra section E1, second Code section C2, and second Extra section E2.

In this case, the first conversion unit 25 generates a first sub-symbol consisting of a first Code section C1 and a first Extra section E1. Specifically, for example, when it is assumed that the size of the first Code section C1 is 5 bits (fixed), the first sub-symbol is generated by filling the first Extra section E1 in vacant bits remaining after the first Code section C1 is placed.

However, as described above, the size of the first Extra section E1 varies depending on the match length, and when the size of the first Extra section E1 is large, the entire first Extra section E1 cannot be fully filled in the vacant bits of the first sub-symbol. In this case, as shown in FIG. 21, the first Extra section E1 may be divided into a first Extra section E11 and a first Extra section E12, and a first sub-symbol including the first Code section C1 and the first Extra section E11 and a second sub-symbol including the first Extra section E12 may be generated.

The first Code section C1 and the first Extra section E1 (i.e., match length) have been described above, but the same applies to the second Code section C2 and the second Extra section E2 (i.e., match distance). It is noted that in the example shown in FIG. 21, the second Extra section E2 is divided into a second Extra section E21 and a second Extra section E22, and a third sub-symbol including the second Code section C2 and the second Extra section E21 and a fourth sub-symbol including the second Extra section E22 are generated.

It is noted that in the present embodiment, a plurality of sub-symbols are generated such that at least the first Code section C1 and the second Code section C2 are output in different cycles (i.e., a sub-symbol including both the first Code section and the second Code section is not generated).

“S0” to “S3” shown in FIG. 21 represent first to fourth sub-symbols generated (converted) from the dictionary match symbol S as described above, and the first to fourth sub-symbols are output from the first conversion unit 25 in different cycles, and stored in the delay buffer 23.

When the first to fourth sub-symbols converted from the dictionary match symbol S are stored in the delay buffer 23 as described above, the first to fourth sub-symbols are read out from the delay buffer 23 in different cycles. The first to fourth sub-symbols thus read out from the delay buffer 23 are converted into a first Code section C1, a first Extra section E1, a second Code section C2, and a second Extra section E2 by second conversion processing.

It is noted that, as described above, when the first sub-symbol includes the first Extra section E11 and the second sub-symbol includes the first Extra section E12, the second conversion unit 26 executes processing of restoring the first Extra section E1 by integrating the first Extra section E11 and the first Extra section E12. Similarly, when the third sub-symbol includes the second Extra section E21 and the fourth sub-symbol includes the second Extra section E22, the second conversion unit 26 executes processing of restoring the second Extra section E2 by integrating the second Extra section E21 and the second Extra section E22.

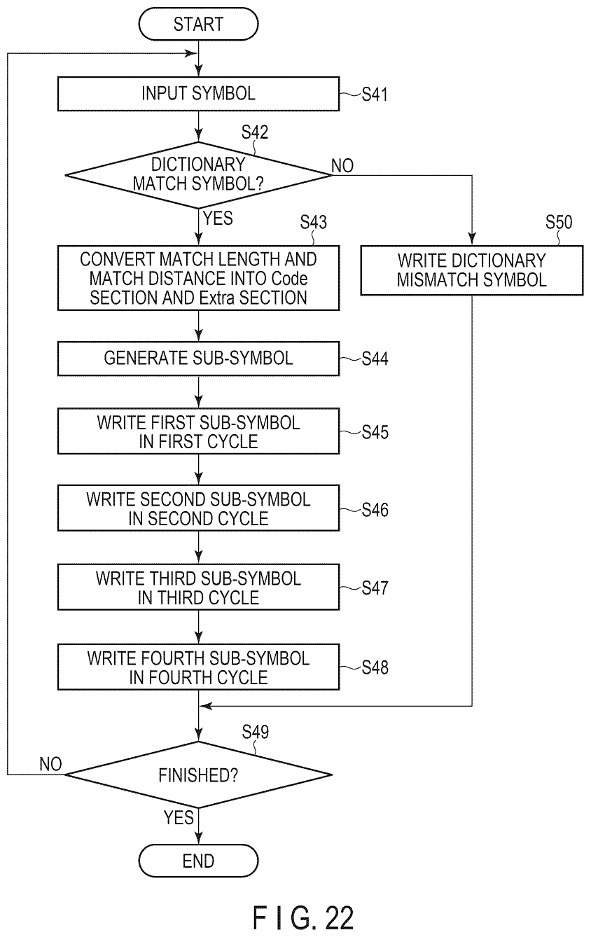

Next, an example of the processing procedure of the first conversion processing in the present embodiment will be described with reference to a flowchart in FIG. 22.

First, the processing of steps S41 and S42 which correspond to the processing of steps S21 and S22 shown in FIG. 15 described above is executed.

When it is determined that an input symbol is a dictionary match symbol (YES in step S42), the first conversion unit 25 converts the dictionary match symbol (a match length and a match distance) into a Code section and an Extra section (step S43).

Furthermore, the first conversion unit 25 generates a plurality of sub-symbols based on the Code section and the Extra section converted from the dictionary match symbol in step S43 (step S44). Here, first to fourth sub-symbols as described in FIG. 21 are assumed to be generated.

In this case, the first conversion unit 25 writes the first sub-symbol into the delay buffer 23 in a first cycle (step S45).

When the processing of step S45 is executed, the first conversion unit 25 writes the second sub-symbol into the delay buffer 23 in a second cycle subsequent to the first cycle (step S46).

When the processing of step S46 is executed, the first conversion unit 25 writes the third sub-symbol into the delay buffer 23 in a third cycle subsequent to the second cycle (step S47).

When the processing of step S47 is executed, the first conversion unit 25 writes the fourth sub-symbol into the delay buffer 23 in a fourth cycle subsequent to the third cycle (step S48).

According to the processing of steps S45 to S48 described above, the first to fourth sub-symbols generated in step S44 are written (output) sequentially into the delay buffer 23 in different cycles. It is noted that the first to fourth sub-symbols are also output to the table generating unit 22 in different cycles.

When the processing of step S48 is executed, the processing of step S49 corresponding to the processing of step S26 shown in FIG. 15 described above is executed.

It is noted that when it is determined that the input symbol is not a dictionary match symbol (NO in step S42), the processing of step S50 which corresponds to the processing of step S27 shown in FIG. 15 described above is executed.

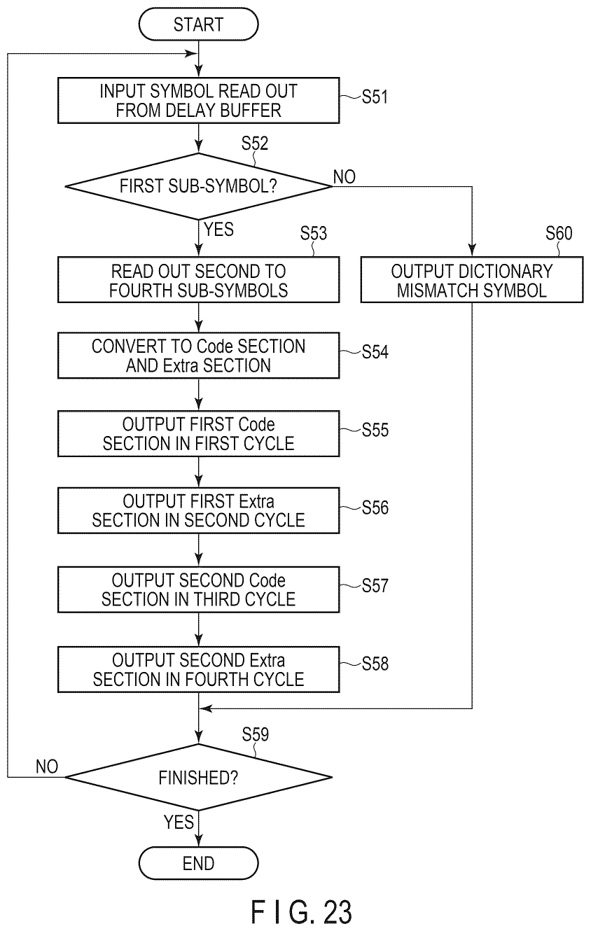

Next, an example of the processing procedure of the second conversion processing in the present embodiment will be described with reference to a flowchart in FIG. 23.

First, the processing of step S51 which corresponds to the processing of step S31 shown in FIG. 16 described above is executed.

Here, according to the first conversion processing described above, the first to fourth sub-symbols generated (converted) from the dictionary match symbol and the dictionary mismatch symbol are stored (written) in the delay buffer 23. Therefore, the second conversion unit 26 determines whether the input symbol is a first sub-symbol (step S52).

When it is determined that the input symbol is the first sub-symbol (YES in step S52), the second conversion unit 26 further reads out, from the delay buffer 23, the second to fourth sub-symbols which have been written into the delay buffer 23 subsequently to the first sub-symbol (step S53).

Here, as described above, the size of the first Extra section E1 differs depending on the match length, and the second sub-symbol may not exist depending on the size of the first Extra section E1. Therefore, according to the value of the first Code section C1 included in the first sub-symbol, the second conversion unit 26 determines whether the second sub-symbol can be read out.

For example, according to the above-mentioned deflate standard, when the value of the first Code section C1 ranges from 0 to 19, it corresponds to a match length of 3 to 66, and the first Extra section E1 ranges from 0 to 3 bits, so that the first Extra section E1 can be stored in the 8 bits of the first sub-symbol together with the 5 bits of the first Code section. In this case, the second conversion unit 26 determines that the second sub-symbol does not exist (i.e., there is no need to read out the second sub-symbol).

On the other hand, when the value of the first Code section C1 ranges from 20 to 28, it corresponds to a match length of 67 to 258, and the first Extra section E1 ranges from 4 to 5 bits, so that a part of the first Extra section E1 (a first Extra section E12) cannot be stored in the 8 bits of the first sub-symbol. In this case, the second conversion unit 26 determines that there exists a second sub-symbol in which a part of the first Extra section E1 is stored (i.e., the second sub-symbol is read out).

The match length has been described above, and the same is applied to the match distance such that depending on the value of the second Code section C2 included in the third sub-symbol, the second conversion unit 26 determines whether the fourth sub-symbol can be read out. In the following, the description will be made on the assumption that the second to fourth sub-symbols have been read out from the delay buffer 23 in step S53.

Next, the second conversion unit 26 converts the input symbol (here, the first sub-symbol) and the second to fourth sub-symbols read out from the delay buffer 23 in step S53 into the first Code section, the first Extra section, the second Code section, and the second Extra section (step S54). It is noted that the processing of step S54 includes, for example, processing of restoring the first Extra section arranged across the first and second sub-symbols, and processing of restoring the second Extra section arranged across the third and fourth sub-symbols.

When the processing of step S54 is executed, the second conversion unit 26 outputs the first Code section (Code section of the match length) to the entropy encoding unit 24 in a first cycle (step S55).

When the processing of step S55 is executed, the second conversion unit 26 outputs the first Extra section (the Extra section of the match length) to the entropy encoding unit 24 in a second cycle subsequent to the first cycle (step S56).

When the processing of step S56 is executed, the second conversion unit 26 outputs the second Code section (the Code section of the match distance) to the entropy encoding unit 24 in a third cycle subsequent to the second cycle (step S57).

When the processing of step S57 is executed, the second conversion unit 26 outputs the second Extra section (the Extra section of the match distance) to the entropy encoding unit 24 in a fourth cycle subsequent to the third cycle (step S58).

According to the processing of steps S55 to S58 described above, the Code section (first and second Code sections) and the Extra section (first and second Extra sections) are time-divisionally output to the entropy encoding unit 24 such that they are output in different cycles.

When the processing of step S58 is executed, the processing of step S59 which corresponds to the processing of step S36 shown in FIG. 16 described above is executed.

It is noted that when it is determined that the input symbol is not the first symbol (i.e., it is a dictionary mismatch symbol) (NO in step S52), the processing of step S60 which corresponds to the processing of step S37 shown in FIG. 16 described above is executed.

When the second conversion processing shown in FIG. 23 described above is executed, the entropy encoding unit 24 sequentially performs entropy coding on the first Code section, the first Extra section, the second Code section, and the second Extra section which are output from the second conversion unit 26 in different cycles.

It is noted that the encoding table to be used for entropy coding in the present embodiment is generated, for example, by recovering the first Code section, the first Extra section, the second Code section, and the second Extra section from the first to fourth sub-symbols and counting the frequency of appearance of each of the first Code section, the first Extra section, the second Code section, and the second Extra section.

As described above, the compression device 2e according to the present embodiment converts a match length included in a dictionary match symbol (first symbol) into a first Code section (first match length section) and a first Extra section (second match length section), converts a match distance included in the dictionary match symbol into a second Code section (first match distance section) and a second Extra section (second match distance section), and generates a plurality of sub-symbols (second symbols) based on the first and second Code sections and the first and second Extra sections. Furthermore, the compression device 2e according to the present embodiment converts a plurality of sub-symbols read out from the delay buffer 23 into first and second Code sections and first and second Extra sections, and performs entropy coding on each of the first and second Code sections and the first and second Extra sections.

Here, the third embodiment has been described above on the assumption that the entropy coding is performed on the match length and the match distance in different cycles. However, when each of the match length and match distance is expressed by a Code section and an Extra section as described above, the entropy coding to be performed in the third embodiment requires a combining circuit for combining a variable-length code assigned to the Code section and a variable-length code assigned to the Extra section.

However, in the present embodiment, the match length and the match distance are further divided (separated) into a Code section (first and second Code sections) and an Extra section (first and second Extra sections), and the entropy coding are performed on the Code section and the Extra section in different cycles (time division), so that the combining circuit required in the third embodiment as described above can be omitted. In other words, according to the present embodiment, as compared with the third embodiment in which the Code section and the Extra section are encoded in the same cycle, the encoding logic is reduced (i.e., the circuit scale of the entropy encoding circuit can be reduced), which makes it possible to implement further miniaturization of the compression device 2e.

It is noted that as described in the present embodiment, when the dictionary match symbol is converted into the first to fourth sub-symbols (i.e., the dictionary match symbol is output over four cycles), it is considered that the throughput of the compression device 2e will decrease in such a case that a dictionary match symbol is generated from non-compressed data input in three cycles. However, since the match length included in the dictionary match symbol generated from the non-compressed data input in three cycles is three, there is no first Extra section as described above, and the second sub-symbol is not generated. Therefore, the number of sub-symbols generated from the dictionary match symbol generated from the non-compressed data input in three cycles is at most three, so that the throughput of the compression device 2e described above will not decrease.

Furthermore, since the present embodiment can use a delay buffer 23 having a width for data of 8 bits, the area of the delay buffer 23 can be made smaller than that in the second and third embodiments.

The present embodiment has been described on the assumption that the entropy coding is performed on each of the Code section and the Extra section, but according to the deflate standard, the entropy coding may be performed only on the Code section.

In this case, the table generating unit 22 may count the frequency of appearance of the Code section (first and second Code sections) included in a plurality of sub-symbols output from the first conversion unit 25 in different cycles, and generates an encoding table in which the variable-length code to be assigned to the Code section is defined according to the frequency of appearance of the Code section.

According to such a configuration, it is possible to omit the mechanism for restoring the Extra section that spans a plurality of sub-symbols in order to generate the encoding table, which is believed to contribute to reduction of the circuit scale.

According to at least one of the above-described embodiments, it is possible to provide a compression device, memory system, and a compression method that can implement miniaturization.

It is noted that the width of the delay buffer and the sizes of various data (e.g., symbols, or the like) described in the first to fourth embodiments are examples for the purpose of description, and may be different from those described in the first to fourth embodiments as long as the miniaturization of the compression device 2e can be implemented.

While certain embodiments have been described, these embodiments have been presented by way of example only, and are not intended to limit the scope of the inventions. Indeed, the novel devices and methods described herein may be embodied in a variety of other forms; furthermore, various omissions, substitutions, and changes in the form of the embodiments described herein may be made without departing from the spirit of the inventions. The accompanying claims and their equivalents are intended to cover such forms or modification as would fall within the scope and spirit of the inventions.

What is claimed is

1. A compression device configured to perform dictionary-based coding and entropy coding on first data that is continuously input, the compression device comprising:
a first encoder configured to perform the dictionary-based coding with respect to the first data to generate a first symbol;
a first converter configured to convert the first symbol into a plurality of second symbols and cyclically output one of the plurality of second symbols per cycle;
a first buffer that stores each of the plurality of second symbols output from the first converter;
a generator configured to generate an encoding table for the entropy coding; and
a second encoder configured to cyclically read out one of the second symbols from the first buffer per cycle after the encoding table is generated, and perform the entropy coding with respect to a bit sequence comprising the plurality of second symbols with reference to the generated encoding table.

2. The compression device according to claim 1, wherein the first buffer comprises a plurality of word lines in each of which one of the second symbols is stored, and data is input to and output from the first buffer per word line.

3. The compression device according to claim 2, wherein the first converter is configured to divide the first symbol into the plurality of second symbols such that a size of each of the plurality of second symbols is equal to or smaller than a bit width of the word lines.

4. The compression device according to claim 1, wherein the plurality of second symbols generated by the first converter has a same bit length.

5. The compression device according to claim 1, further comprising:
a second converter configured to convert the plurality of second symbols read out from the first buffer into the first symbol, wherein
the second encoder is configured to perform the entropy coding with respect to the first symbol output from the second converter.

6. The compression device according to claim 5, wherein
the generator is configured to count a frequency of appearance of the first symbol generated by the first encoder, and generate the encoding table, in which a variable-length code to be assigned to the first symbol is defined according to the frequency of appearance of the first symbol, and
the second encoder is configured to generate the variable-length code assigned to the first symbol with reference to the encoding table during the entropy coding.

7. The compression device according to claim 5, wherein
the generator is configured to count a frequency of appearance of each of the plurality of second symbols cyclically read out from the first converter, and generate the encoding table, in which a variable-length code to be assigned to each of the plurality of second symbols is defined according to the frequency of appearance of the second symbol, and
the second encoder is configured to generate the variable-length code assigned to the first symbol with reference to the encoding table during the entropy coding.

8. The compression device according to claim 5, wherein
the first encoder includes a second buffer that stores second data previously input to the compression device, and
the first symbol comprises a bit sequence representing a match length, which is a bit length of a portion of the first data that coincides with the second data, and a bit sequence representing a match distance, which is a storage location of the second data in the second buffer.

9. The compression device according to claim 8, wherein the first converter is configured to convert the first symbol into a second symbol representing the match length and a second symbol representing the match distance.

10. The compression device according to claim 9, wherein the second symbol representing the match length has a different bit length from the second symbol representing the match distance.

11. The compression device according to claim 9, wherein the generator is configured to count a frequency of appearance of each of the second symbol representing the match length and the second symbol representing the match distance, and generate the encoding table, in which a variable-length code to be assigned to symbols representing the match length and symbols representing the match distance is defined according to the frequency of appearance thereof.

12. The compression device according to claim 11, wherein the second encoder comprises:
a first multiplexer configured to output a first variable-length code to be assigned to the second symbol representing the match length;
a second multiplexer configured to output a second variable-length code to be assigned to the second symbol representing the match distance; and
a combing circuit configured to combine the first variable-length code and the second variable-length code to output a variable-length code assigned to the first symbol.

13. The compression device according to claim 8, wherein
the first converter is configured to convert the first symbol into a first plurality of second symbols of a same bit length representing the match length and a second plurality of second symbols of a same bit length representing the match distance,
the first plurality of second symbols comprises a first variable bit sequence representing the match length and a first extra bit sequence, and
the first plurality of second symbols comprises a second variable bit sequence representing the match distance and a second extra bit sequence.

14. The compression device according to claim 13, wherein the generator is configured to count a frequency of appearance of each of the first variable bit sequence and the second variable bit sequence, and generate the encoding table, in which a variable-length code to be assigned to the first variable bit sequence and the second variable bit sequence is defined according to the frequency of appearance thereof.

15. The compression device according to claim 1, wherein
the generator is configured to count a frequency of appearance of each of the plurality of second symbols cyclically read out from the first converter, and generate the encoding table, in which a variable-length code to be assigned to each of the plurality of second symbols is defined according to the frequency of appearance of the second symbol, and
the second encoder is configured to generate the variable-length code assigned to each of the plurality of second symbols with reference to the encoding table during the entropy coding.

16. The compression device according to claim 15, wherein the second encoder comprises a multiplexer configured to cyclically output a variable-length code to be assigned to one of the plurality of second symbols per cycle.

17. A memory system comprising:
a controller including the compression device according to claim 1; and
a non-volatile memory, wherein
the controller is configured to store, into the non-volatile memory, data that has been subjected to the entropy coding and output from the compression device.

18. A compression method to be executed by a compression device that is configured to perform dictionary-based coding and entropy coding on first data that is continuously input, the compression method comprising:
generating a first symbol by performing the dictionary-based coding with respect to the first data to generate a first symbol;
converting the first symbol into a plurality of second symbols and cyclically outputting one of the plurality of second symbols per cycle;
storing, in a first buffer, each of the plurality of second symbols converted from the first symbol;
generating an encoding table for the entropy coding; and
cyclically reading out one of the second symbols from the first buffer per cycle after the encoding table is generated, and performing the entropy coding with respect to a bit sequence comprising the plurality of second symbols with reference to the generated encoding table.
